(19) United States
(12) Patent Application Publication
(10) Pub. No.: US 2009/0266413 A1
(43) Pub. Date: Oct. 29, 2009

(54) Photovoltaic Cells With Gratings For Scattering Light Into Light-absorption Layers

(76) Inventors: Sagi Mathai, Palo Alto, CA (US); David Fattal, Mountain View, CA (US); Shih-Yuan Wang, Palo Alto, CA (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/262,147

(22) Filed: Oct. 30, 2008

Related U.S. Application Data
(60) Provisional application No. 61/125,544, filed on Apr. 25, 2008.

(51) Int. Cl. H01L 31/00

(52) U.S. Cl. 136/256

(57) ABSTRACT

Embodiments of the present invention are directed to photovoltaic cells that include a surface relief grating to couple out-of-plane light into the leaky slab modes of the photovoltaic cells. In one embodiment of the present invention, a photovoltaic cell comprises a bottom electrode, a light-absorption layer disposed on the bottom electrode, and a top electrode disposed on the light-absorption layer. The top electrode is configured with a grating that enables light incident on the grating to be scattered into the light-absorption layer and traps incident light with particular polarizations and incident angles in the grating to interact with the light-absorption layer.

### CROSS-REFERENCE TO RELATED APPLICATION

The present application claims priority from provisional application Ser. No. 61/125,544, filed Apr. 25, 2008, the contents of which are incorporated herein by reference in their entirety.

### TECHNICAL FIELD

Embodiments of the present invention relate to photovoltaic cells.

### BACKGROUND

Photovoltaic cells are devices that convert light energy into electricity via a light-absorbing material. The electricity can flow through wires to power electronic devices. A solar cell is a type of photovoltaic cell configured to capture and convert sunlight into electricity. Assemblies of solar cells can be arrayed into modules, which, in turn, can be linked together into solar arrays. These arrays can be used to generate electricity in places where a power grid is not available, such as in remote area power systems, Earth-orbiting satellites and space probes, remote radio, telephone, and water pumping systems. In recent years, due to the increasing costs of generating electricity from fossil fuels, the demand for solar arrays to supplement home and commercial electrical power needs has increased.

However, most conventional photovoltaic cells only convert a small fraction of the light received into electricity. For example, efficiencies vary from about 6 to about 10% for amorphous silicon-based photovoltaic cells to about 43% for multiple junction-based photovoltaic cells. In addition, mass producing the more efficent multiple junction photovoltaic cells to form photovoltaic arrays may be cost prohibitive. For example, the cost of mass producing a multiple junction photovoltaic cell may be as much as 100 times greater than the cost of producing a less efficient amorphous silicon-based cell. The efficiency of many conventional photovoltaic cells is also proportional to the thickness of light-absorption layers. Increasing efficiency by thickening the light-absorption layers is offset by the higher cost of raw materials. Thus, engineers and physicists have recognized a need for high-efficiency, low-cost photovoltaic cells.

### SUMMARY

Embodiments of the present invention are directed to photovoltaic cells that include a grating to couple out-of-plane light into the leaky slab modes of the photovoltaic cells. In one embodiment of the present invention, a photovoltaic cell comprises a bottom electrode, a light-absorption layer disposed on the bottom electrode, and a top electrode disposed on the light-absorption layer. The top electrode is configured with a grating that enables light incident on the grating to be scattered into the light-absorption layer and traps incident light with particular polarizations and incident angles in the grating to interact with the light-absorption layer.

### BRIEF DESCRIPTION OF THE DRAWINGS

FIG. 1A shows a side elevation of a p-n junction photovoltaic cell.

FIG. 1B shows an electronic energy-band diagram for the semiconductor layers of the photovoltaic cells shown in FIG. 1A.

FIG. 2A shows an isometric view of a first photovoltaic cell configured in accordance with embodiments of the present invention.

FIG. 2B shows a cross-sectional view of the first photovoltaic cell along a line I-I, shown in FIG. 2A, in accordance with embodiments of the present invention.

FIG. 3 shows an isometric view of a second photovoltaic cell configured in accordance with embodiments of the present invention.

FIG. 4 shows an isometric view of a third photovoltaic cell configured in accordance with embodiments of the present invention.

FIG. 5A shows an exploded isometric view of a fourth photovoltaic cell configured in accordance with embodiments of the present invention.

FIG. 5B shows a cross-sectional view the first photovoltaic cell along a line II-II, shown in FIG. 5A, in accordance with embodiments of the present invention

FIG. 6A shows a side elevation of a light-absorption layer configured with a nanowire-based middle layer in accordance with embodiments of the present invention.

FIG. 6B shows a side elevation of a conductive layer sandwiched between a grating and a light-absorption layer of a photovoltaic cell configured in accordance with embodiments of the present invention.

FIG. 7 shows a sinusoidal wave representing the electric field component of light resonating in a grating of a top electrode in accordance with embodiments of the present invention.

FIGS. 8A-8B show cross-sectional views of light incident on a photovoltaic cell configured in accordance with embodiments of the present invention.

FIG. 9 shows combining photovoltaic cells to produce a photovoltaic panel in accordance with embodiments of the present invention.

### DETAILED DESCRIPTION

Embodiments of the present invention are directed to photovoltaic cells that include a grating to couple out-of-plane light into the slab modes of the photovoltaic cells. A conventional photovoltaic cell converts less than half of incident light into electricity via a light-absorption layer. Most of the incident light is reflected and a smaller portion passes through the light-absorption layer unabsorbed. Thus, the operation of a conventional photovoltaic cell relies on having a relatively thick light-absorption layer to convert as much incident light into electrical power as possible. In contrast, the photovoltaic cells of the present invention do not rely on employing thick light-absorption layers to convert a portion of the incident light into electrical energy. Photovoltaic cells of the present invention have a relatively higher efficiency than conventional photovoltaic cells because the grating scatters and traps much of the incident light within the light-absorption layer so that more light is available for absorption and much less light is lost due to reflection and transmission than in conventional photovoltaic cells. The rate of light scattering into the grating mode is substantially equal to the rate of light absorption in the light-absorption layer. Because more light is available for a longer period of time within the light-absorption layer, the light-absorption layer can more efficiently convert incident light into electrical power, and, as a result, the light-absorption layer can be made thinner than the light-absorption layer of a conventional photovoltaic cell.

### General Operation of Light-Absorption Layers of Photovoltaic Cells

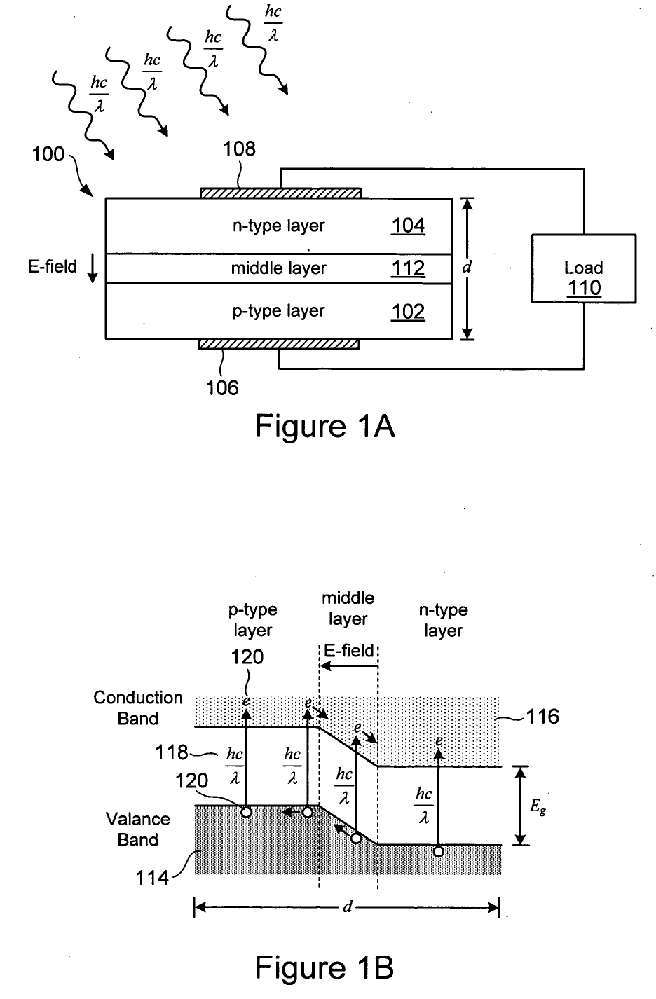

FIG. 1A shows a schematic representation of a p-n junction photovoltaic cell 100. The cell 100 comprises a p-type semiconductor layer 102 and an n-type semiconductor layer 104. A first electrode 106 is disposed on the p-type layer 102, and a second electrode 108 is disposed on the n-type layer 104. The electrodes 106 and 108 are connected to a load 110, such as an electronically operated device. The p-type layer 102 is doped with electron accepting impurities or acceptors having fewer electrons than the surrounding atoms in the semiconductor lattice creating vacant electronic energy states that can be characterizes as positively charged holes. In contrast, the n-type layer 104 is doped with electron donating impurities or donors that donate electrons to the semiconductor lattice. The electrons and holes are called mobile “charge carriers.” A middle layer 112 sandwiched between the p-type layer 102 and the n-type layer 104 can be composed of a separate intrinsic semiconductor material or it can be formed between the p-type layer 102 and the n-type layer 104 as a result of electrons diffusing from the n-type layer 104 into the p-type layer 102 and holes diffusing from the p-type layer 102 into the n-type layer 104. The uncompensated acceptors in the p-type layer 102 and uncompensated donors in the n-type layer 104 form the layer 112. The uncompensated acceptors and donors generate an electric field directed from the interface between the layer 112 and the n-type layer 104 to the interface between the deplection layer 112 and the p-type layer 102. This electric field forces electrons and holes in the layer 112 to drift back into the n-type layer 104 and the p-type layer 102, respectively. Ultimately, an equilibrium is reached where the number of electrons and holes diffusing across the pn-junction equals the number of electrons and holes drifting across the pn-junction, and the net current flow tends to zero. The layers 102, 104, and 112 form the light-absorption layers of the photovoltaic cell 100.

FIG. 1B shows an electronic energy-band diagram associated with the light-absorption layers 102, 104, and 112. Heavily shaded layers, such as layer 114, represent a continuum of mostly filled electronic energy states in the valance band, lightly shaded layers, such as layer 116, represent a continuum of mostly empty electronic energy states in the conduction band, and unshaded layers, such as layer 118, represent the electronic band gap where no electronic energy states exists. Electron donating impurities contribute electrons to electronic states near the conduction band while electron accepting impurities remove electrons from electronic states near the valence band leaving behind holes. Thus, the valance and conduction bands associated with the p-type layer 102 are higher in electronic energy than the valance and conduction bands associated with n-type layer 104.

The photovoltaic cell 100 is positioned so that photons of incident light, shown in FIG. 1A, can penetrate the layers 102, 104, and 112. As shown in FIG. 1B, when the incident photons have energies satisfying the condition:

$$\frac{hc}{λ} \geq {E}_{g}$$

where h is Plank's constant and λ is the wavelength of the photon, the photons are absorbed and electrons, denoted by “e,” are excited from the valance band into the conduction band creating electron-hole pairs, such as electron-hole pair 120. The force of the electric field across the layer 112 drives electrons in the conduction bands of the layers 102, 104, and 112 through the top electrode 108 to power the load 110. The electrons continue to provide electrical power until they recombine with holes.

The electronic bandgap energy shown in FIG. 1B is the same for all three layers 102, 104, and 112. This may be the result of all three layers being composed of the same semiconductor material. In other words, the layers 102, 104, and 112 form a homojunction solar cell. Silicon-based solar cells are one example of homojunction solar cells. In contrast, the most efficient solar cells are typically heterojunction solar cells. In a heterojunction solar cell, the p-type and n-type layers 102 and 104 are composed of semiconductor materials that have larger electronic bandgap energies than the middle layer 112. For example, the p-type and n-type layers 102 and 104 of a heterojunction solar cell can be composed of AlGaAs and the middle layer 112 can be composed GaAs.

Ideally, the middle layer 112 forms the light-absorption layer of the photovoltaic cell 100, where layers 102 and 104 are transparent to the incident light. The most efficient photovoltaic cells have the electron-hole pairs generated by photons in the layer 112, which has the highest electric field for sweeping out the charge carriers to create the external electric current. Electron-hole pairs generated in the layers 102 and 104 need to diffuse into the high electric field region of the layer 112 to generate an external current. Occasionally, electron-hole pairs can recombine at defects and surface states before the pairs can be separated resulting in a decrease in efficiency of the photovoltaic cell 100.

### Embodiments of the Present Invention

### I. Photovoltaic Cells

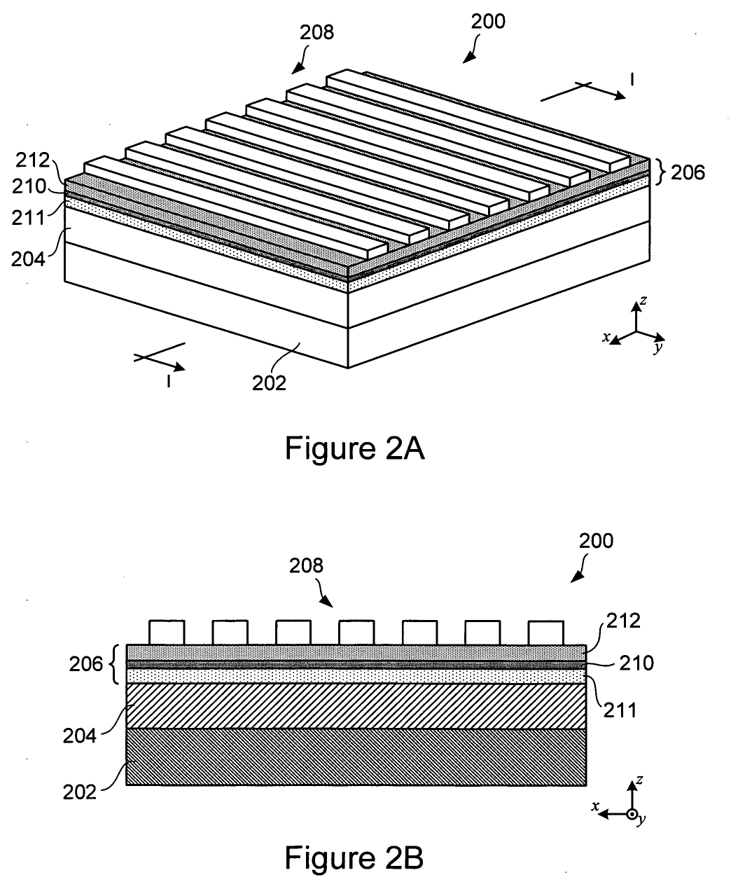

FIG. 2A shows an isometric view of a first photovoltaic cell 200, and FIG. 2B shows a cross-sectional view the first photovoltaic cell 200 along a line I-I, shown in FIG. 2A, in accordance with embodiments of the present invention. The first photovoltaic cell 200 is composed of a substrate 202, a bottom electrode 204 disposed on the substrate 202, a light-absorption layer 206 disposed on the bottom electrode 204, and a top electrode 208 disposed on the light-absorption layer 206. The light-absorption layer 206 is composed of a middle layer 210 sandwiched between a bottom semiconductor layer 211 and a top semiconductor layer 212. As shown in FIGS. 2A-2B, the electrode 208 is composed of an array of seven substantially regularly spaced bars separated by gaps to form a grating on the top surface of the light-absorption layer 206. Note that embodiments of the present invention are not limited to seven bars. In other embodiments, the electrode can be composed of eight or more bars.

The light-absorption layers 210-212 can be composed of indirect band gap semiconductors and direct band gap semiconductors depending on cost, efficiency, and/or the range of wavelengths of incident light to be converted into electrical power. In certain embodiments, the light-absorption layers 210-212 can be composed of amorphous or crystalline silicon (“Si”). In other embodiments, the light-absorption layers 210-212 can be composed of direct band gap compound semiconductors. Compound semiconductors are typically III-V materials, where Roman numerals III and V represent elements in the IIIa and Va columns of the Periodic Table of the Elements. In particular, suitable column IIIa elements include Al, Ga, and In, and suitable column Va elements include N, P, arsenic (“As”), and antimony (“Sb”). Compound semiconductors can be classified according the quantities of III and V elements comprising the semiconductor. For example, binary semiconductor compounds include GaAs, InP, InAs, and GaP; ternary semiconductor compounds include GaAs_{y}P_{1-y}, where y ranges between 0 and 1; and quaternary semiconductor compounds include InₓGa₁₋ₓAs_{y}P_{1-y}, where both x and y independently range between 0 and 1. Other types of suitable compound semiconductors include II-VI materials, where II and VI represent elements in the IIb and VIa columns of the periodic table. For example, cadmium (“Cd”) and zinc (“Zn”) are examples of suitable column IIb elements, and selenium (“Se”), sulfur (“S”), and oxygen (“O”) are examples of suitable column VIa elements. The column IIb and VIa elements can be combined to form binary II-VI compound semiconductors, such as CdSe, ZnSe, ZnS, and ZnO, and ternary and quaternary compound semiconductors.

In certain embodiments, the top semiconductor layer 212 is an n-type semiconductor while the bottom semiconductor layer 211 is a p-type semiconductor. In other embodiments, the top semiconductor layer 212 is a p-type semiconductor while the bottom semiconductor layer 211 is an n-type semiconductor. An n-type semiconductor is semiconductor doped with electron donating impurities or donors, such as nitrogen (“N”), phosphorous (“P”), and selenium (“Se”), and a p-type semiconductor is a semiconductor doped with electron accepting impurities or acceptors, such as boron (“B”), aluminum (“Al”), gallium (“Ga”), and indium (“In”). The middle layer 210 can be the depletion layer of a p-n junction light-absorption layer 206 formed as a result of electron and hole diffusion and drift, or, in other embodiments, the layer 210 can be a separate intrinsic semiconductor layer of a p-i-n junction light-absorption layer 206.

The substrate 202 can be composed of a rigid dielectric material such as Si, glass, SiO₂, and Si₃N₄, or a flexible dielectric material such as acrylic or another suitable dielectric substrate. The bottom electrode 204 can be composed of a metal conductor such as stainless steel, aluminum, copper, or any other suitable conducting material. In certain embodiments, the substrate may be a rigid or flexible metal conductor such as stainless steel, aluminum, copper, or any other suitable conducting material. The top electrode 208 can be composed of a metal conductor such as stainless steel, aluminum, copper, or the top electrode 208 can be composed of a transparent conducting material, such as tin-doped indium oxide (“ITO”).

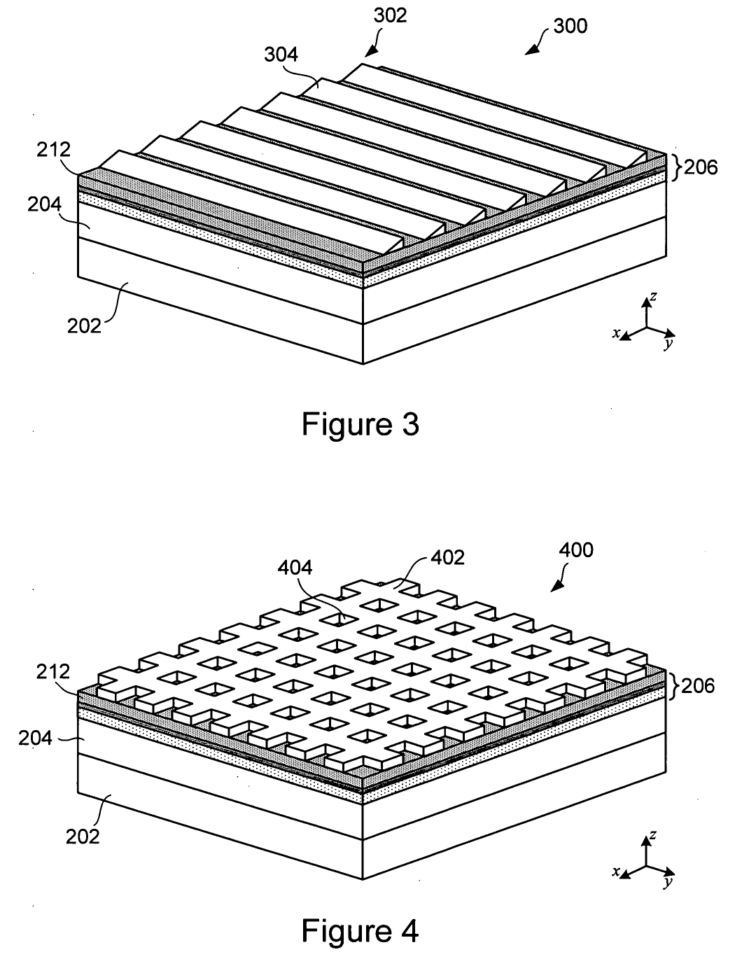

As shown in FIG. 2, the top electrode 208 can be configured with substantially parallel bars or wires having rectangular cross-sections disposed on the n-type layer 212. In other embodiments, the bars composing the top electrode can have square cross sections, trapezoidal cross sections, semicircular cross sections with the flat portions disposed on the top semiconductor layer 212, or more complex cross sections. The bars may also have many different widths and aspect ratios or eccentricities. FIG. 3 shows an isometric view of a second photovoltaic cell 300 having a top electrode 302 composed of bars, such as bar 304, disposed on the top semiconductor layer 212 with triangular-shaped cross section in accordance with embodiments of the present invention. The thickness of the grating can range from about 50 nm to about 100 nm, the width of the bars composing the grating can range from about 50 nm to about 500 nm, and the pitch of the bars can range from about 100 nm to about 1000 nm depending on the spectral region that is targeted.

Instead of the grating being composed of substantially parallel bars, the grating can be a grid. FIG. 4 shows an isometric view of a third photovoltaic cell 400 having a top electrode 402 composed of an array of holes, such as hole 404, formed in a conductive slab or layer disposed on the top semiconductor layer 212 configured in accordance with embodiments of the present invention. The grating in the top electrode 402 has a square unit cell pattern of substantially square-shaped holes. In other embodiments, the hole shapes can be circular, rectangular, elliptical, or any other suitable shape, and the unit cell pattern can be triangular, hexagonal, or any other suitable unit cell arrangement of holes. In certain embodiments the gaps and holes can be empty or the gaps and holes can be filled with a dielectric material having a different refractive index than that of the slab. The holes can have diameters ranging from 50 nm to 500 nm and a lattice period ranging from 100 nm to 1000 nm.

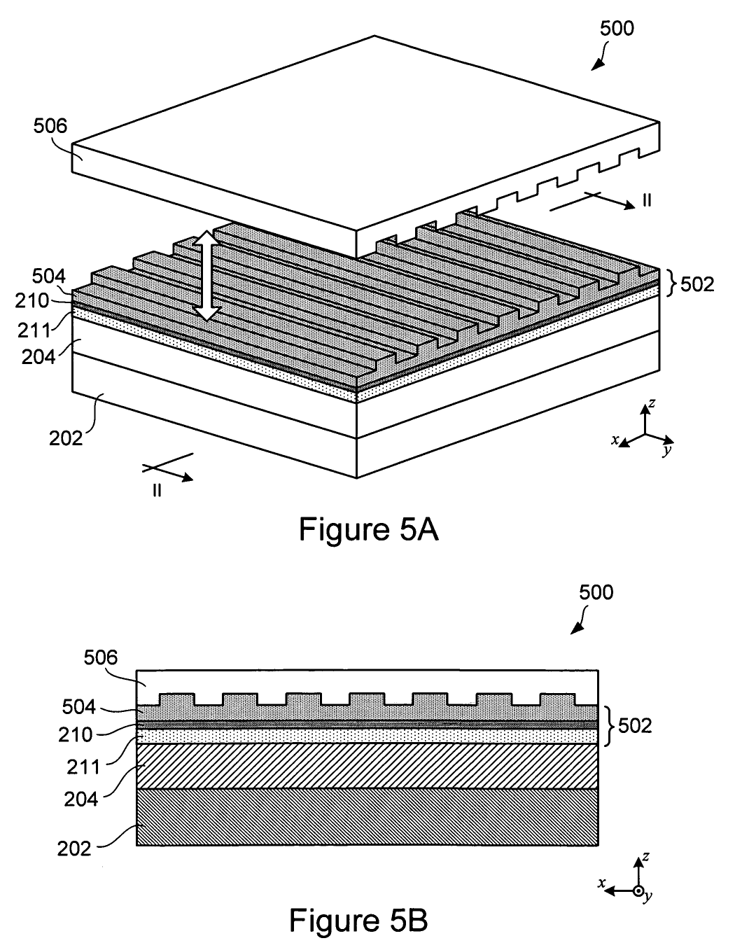

In other photovoltaic cell embodiments, the top semiconductor layer of the light-absorption layer can be configured with a grating. FIG. 5A shows an exploded isometric view of a fourth photovoltaic cell 500, and FIG. 5B shows a cross-sectional view the first photovoltaic cell 500 along a line II-II, shown in FIG. 5A, in accordance with embodiments of the present invention. The photovoltaic cell 500 is nearly identical to the photovoltaic cell 200 except the light-absorption layer 502 is composed of a grated top semiconductor layer 504 disposed on the middle layer 210. The grating in the top semiconductor layer 504 is composed of ridges separated by grooves. The top electrode 506 is also grated with ridges separated by grooves and, as shown in FIG. 5B, is disposed on the top semiconductor layer 504 so that ridges of the top electrode 506 fit within the grooves of the top semiconductor layer 504. The configuration of the grating in the top semiconductor layer 504 is not limited to the grating shown in FIG. 5A, but can also be configured as described above with reference to FIGS. 3-4.

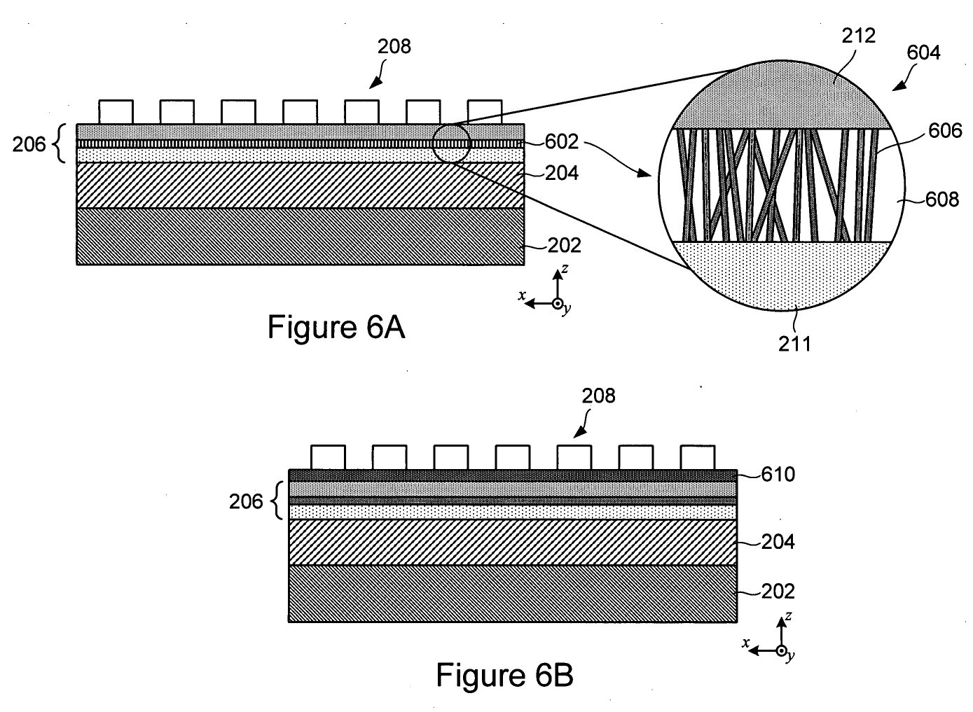

In other embodiments, the light-absorption layers 206 and 502 described above can be configured with a nanowire-based middle layer. FIG. 6A shows a side elevation of the first photovoltaic cell 200 where the light-absorption layer 206 includes a nanowire-based middle layer 602 configured in accordance with embodiments of the present invention. FIG. 6A also includes an enlarged view 604 of the light-absorption layer 206 revealing a portion of the nanowire-based middle layer 602 sandwiched between the bottom semiconductor layer 211 and the top semiconductor layer 212. The nanowire-based middle layer 602 can be composed of an intrinsic semiconductor nanowires extending from the top of the bottom semiconductor layer 211 to the bottom of the top semiconductor layer 212, such as nanowire 606. The nanowire-based middle layer 602 also includes a dielectric material 608 that substantially fills the space between nanowires and between the top and bottom semiconductor layers 211 and 212. The intrinsic nanowires sandwiched between the bottom and top semiconductor layers 211 and 212 forms a p-i-n junction light-absorption layer 206. The nanowires may also be doped to form a p-i-n junction within the nanowires.

In other embodiments, a thin transparent or partially transparent conductive layer can be sandwiched between the grating 208 and the light-absorption layer 206. FIG. 6B shows a side elevation of a conductive layer 610 sandwiched between the grating 208 and the light-absorption layer 206 in accordance with embodiments of the present invention. In this case, the grating 208 can be composed of a transparent dielectric such as SiO₂, Si₃N₄, or other suitable dielectric or metallic material, and the conductive layer 610 can be composed of ITO or another suitable transparent or partially transparent conductive material.

### II. Top Electrode Gratings

In general, the operating mechanism of a top electrode configured with a grating depends on a guided resonance phenomenon. In the case of the photovoltaic cell 500, these guided resonances are leaky optical slab modes confined within the light-absorption layers below the grating. They are considered leaky modes since the grating couples them to radiation modes. The light-absorption layers can be composed of materials that absorb light of a particular wavelength or wavelengths. The grating provides the additional momentum or phase matching mechanism to couple light incident on the grating into the slab modes of the light-absorption layers below the grating. In addition, the grating simultaneously scatters light from the optical slab modes of the light-absorption layers into free space.

In the case of the grating disposed on the surface of the light-absorption layer 206, such as photovoltaic cells 200, 300, and 400, the periodic index contrast created by the lower reflective index holes, or gaps between bars, provides a phase matching mechanism that allows both the coupling of incident light into the confined modes of the light-absorption layers, and the scattering of the guided modes into free space, giving the resonance a finite lifetime.

The optical resonance frequency and lifetime of the guided resonances are determined by the structure of the grating, which provides tremendous flexibility for engineering particular optical properties. The following is a general description regarding the operation of top electrode gratings, and incident light upon the grating are represented in terms of the electric field component of a single incident electromagnetic wave.

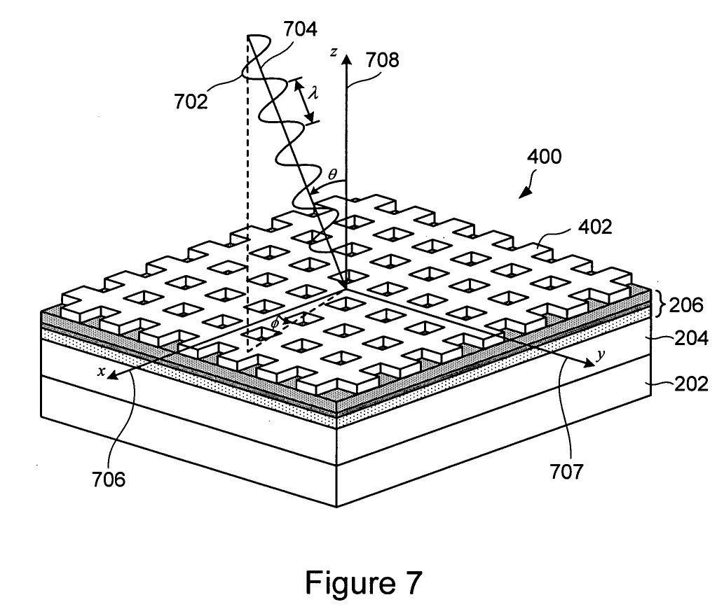

The grating disposed on the light-absorption layer can be configured to amplify incident light over a range of frequencies or wavelengths. Incident light becomes trapped within the grating and continues to build over time, which, in turn, increases the strength of the electric field component and its interaction with the light-absorption layer. As a result, there can be increased light absorption even in a relatively thin light-absorption layer. FIG. 7 shows a sinusoidal wave 702 representing oscillation of the electric field component of a ray of light 704 incident on the top electrode grating 402 of the photovoltaic cell 400. Axes 706-708 represent the x, y, and z Cartesian coordinate axes, respectively. The ray 704 has an associated wave vector:

$$\begin{matrix}{k}^{v} = {k}_{x} \hat{x} + {k}_{y} \hat{y} + {k}_{z} \hat{z} \\ = k ( sin θ cos φ \hat{x} + sin θ sin φ \hat{y} + cos θ \hat{z} )\end{matrix}$$

where k is the wave number of the ray 704, and the parameters θ and φ are the incident angles of the electromagnetic wave. Incident rays can be transmitted through the top electrode grating 402 and can interact with the light-absorption layer to generate electrical power, as described above with reference to FIG. 1. There are other incident rays that are not transmitted through the grating of the top electrode 402. These rays have a particular electromagnetic wave polarization, wavelength λ, and incident angles θ and φ that enables the electromagnetic waves to couple with the lattice structure of the grating and have a resonance within the xy-plane of the grating of the top electrode. For example, consider the electromagnetic wave 702 with a particular polarization and wavelength λ incident upon the top electrode 402. For a large number of incident angles θ and φ, the top electrode 402 is transparent to the incident electromagnetic wave 702. However, there exists a pair of incident angles θ₀ and φ₀ for which the incident electromagnetic wave has a resonance frequency f₀ within the xy-plane of the top electrode grating 402. In other words, the top electrode 402 serves as a Bragg reflector for the electromagnetic wave, and the top electrode 402 is not transparent to this electromagnetic wave with wave vector angles θ₀ and φ₀. This resonance phenomenon is the result of the coupling between the incident electromagnetic wave 702 and the electromagnetic radiation modes that can be supported by the grating of the top electrode 402.

The resonance frequency, or resonance, f₀ is the frequency at which the electromagnetic wave vibrates with the largest amplitude Aₘₐₓ or vibrational energy Eₘₐₓ (≈Aₘₐₓ²). The resonance frequency f₀ is determined by the dielectric constant ε, the lattice constant, the hole width, and the thickness of the grating. The quality (“Q”) factor is one way to qualitatively assess the resonance frequency of a top electrode grating. The following is a brief, but general, description of the Q factor and how the Q factor can be used to qualitatively characterize energy loss for vibrating systems. The Q factor compares the frequency at which a system oscillates to the rate at which the system losses energy. A relatively large Q factor indicates a low rate of energy dissipation relative to the resonance frequency of the system. In general, the Q factor can be represented by:

$$Q \approx \frac{{f}_{0}}{Δ f}$$

where Δf is the range of frequencies for which the vibrational energy of the physical system is at least one-half of the maximum vibrational energy Eₘₐₓ at f₀.

The Q factor associated with the resonance of an electromagnetic wave resonating in the xy-plane of a grating of a top electrode is proportional to:

$$Q \approx \frac{1}{( {ɛ}_{g} - {ɛ}_{h} ) {V}_{hole}}$$

where ε_{g} is the dielectric constant of the grating, εₕ is the dielectric constant of the holes or gaps between bars, and Vₕₒₗₑ is the volume of one hole, and w is the width of the grating. Note that the Q factor increases hole volume Vₕₒₗₑ decreases, or as the difference (ε_{g}−εₕ) decreases. An electromagnetic wave resonating in the grating of a top electrode with a large Q factor resonates with a larger amplitude or more vibrational energy than an electromagnetic wave with a small associated Q factor. In addition, a small Q factor indicates that the resonance of an electromagnetic wave is short lived, while a large Q factor indicates that the resonance of an electromagnetic wave remains trapped in the top electrode grating for a longer period of time and therefore has a longer interaction time with the light-absorption layer 206.

The grating in the top electrode provides at least two advantages over conventional photovoltaic cells to increase interaction of the incident light with the light-absorption layer. First, the grating can scatter light into the light-absorption layer such that the light propagates in the plane of the photovoltaic cell and over a distance much larger than the thickness of the light-absorption layers. Second, the thickness, bar width, gap and/or hole width of the grating and materials composing the top electrode can be selected to create a strong resonance with particular polarization states and incidence angles of the light incident on the grating.

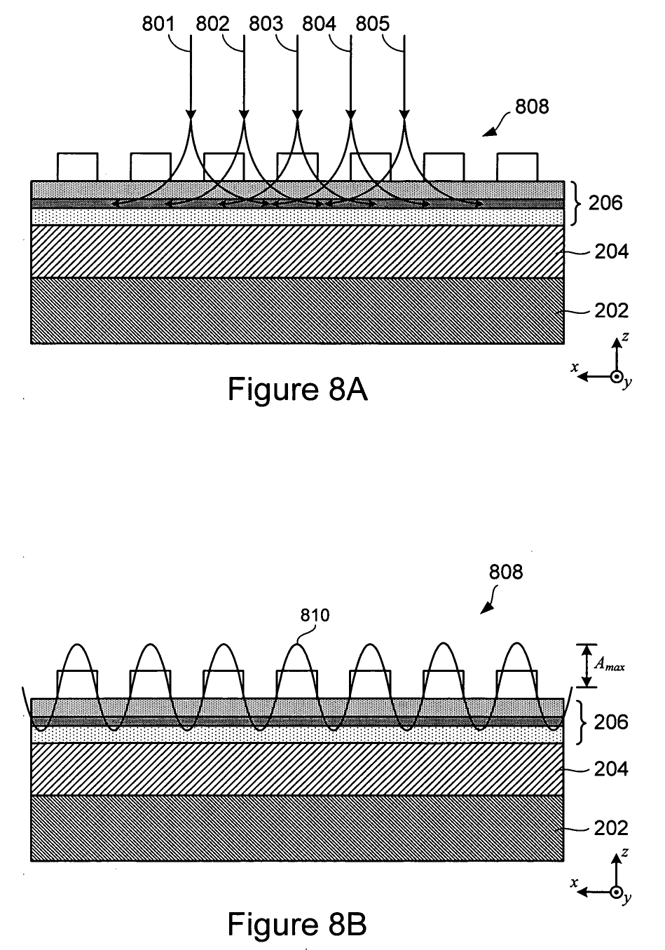

FIGS. 8A-8B show cross-sectional views of a photovoltaic cell configured in accordance with embodiments of the present invention. In FIG. 8A, rays 801-805 of out-of-plane incident light are transmitted through a grating of a top electrode 808 into the light-absorption layer 206. As shown in FIG. 8A, the grating scatters the rays of incident light into the light-absorption layer 206 and thereby increases interaction of the incident light with light-absorption layer 206. As a result, the grating prevents much of the light from being reflected back and more light is available to interact with the light-absorption layer 206. FIG. 8B shows a sinusoidal wave 810 representing the electric field component of light trapped and resonating within the grating of the top electrode 808. As described above, the configuration of the grating converts incident light with a particular polarization and incidence angle into modes that resonate within the grating and, as a result, propagate in the xy-plane of the grating. These modes become concentrated within the grating, and, as shown in FIG. 8B, the thickness of the light-absorption layer 206 can be made thin enough so that much of the light trapped resonating within the grating interacts with the layers of the light-absorption layer 206 thereby increasing the efficiency of the photovoltaic cell 800.

### III. Integrating Photovoltaic Cells into Photovoltaic Panels

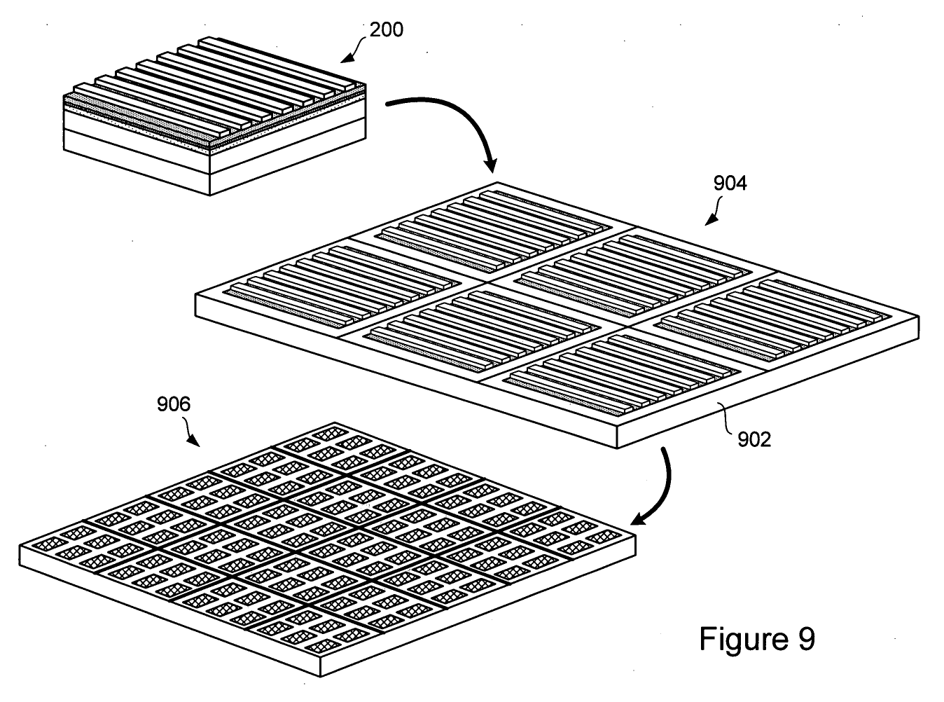

The photovoltaic cells of the present invention can be arrayed to form photovoltaic modules, which, in turn, can be electrically connected to form photovoltaic panels. FIG. 9 shows combining photovoltaic cells 200 to produce a photovoltaic panel in accordance with embodiments of the present invention. In FIG. 9, six nearly identical photovoltaic cells 200 are electrically connected and packaged in a support structure or frame 902 to form a photovoltaic module 904. Photovoltaic modules of the present invention are not limited to six photovoltaic cells, but can be fabricated with any suitable number of cells to produce a desired voltage level. FIG. 9 also shows twenty photovoltaic modules electrically connected in series or parallel to form a photovoltaic panel 906. Photovoltaic panel embodiments are not limit to the number and arrangement of modules of the photovoltaic panel 906. The number and arrangement of modules can vary depending on use and the amount of electrical power desired.

The foregoing description, for purposes of explanation, used specific nomenclature to provide a thorough understanding of the invention. However, it will be apparent to one skilled in the art that the specific details are not required in order to practice the invention. The foregoing descriptions of specific embodiments of the present invention are presented for purposes of illustration and description. They are not intended to be exhaustive of or to limit the invention to the precise forms disclosed. Obviously, many modifications and variations are possible in view of the above teachings. The embodiments are shown and described in order to best explain the principles of the invention and its practical applications, to thereby enable others skilled in the art to best utilize the invention and various embodiments with various modifications as are suited to the particular use contemplated. It is intended that the scope of the invention be defined by the following claims and their equivalents:

1. A photovoltaic cell comprising:
a bottom electrode;
a light-absorption layer disposed on the bottom electrode; and
a top electrode disposed on the light-absorption layer, the top electrode configured with a grating that enables light incident on the grating to be scattered into the light-absorption layer and traps incident light with particular polarizations and incident angles in the grating to interact with the light-absorption layer.

2. The photovoltaic cell of claim 1 wherein the light-absorption layer further comprises:
an n-type-semiconductor layer;
a p-type semiconductor layer; and
a middle layer sandwiched between the n-type semiconductor layer and the p-type semiconductor layer.

3. The photovoltaic cell of claim 2 wherein the middle layer further comprises intrinsic nanowires extending from the n-type semiconductor layer to the p-type semiconductor layer.

4. The photovoltaic cell of claim 1 wherein the light-absorption layer is one of:
a p-n junction; and
a p-i-n junction.

5. The photovoltaic cell of claim 1 wherein the light-absorption layer further comprises one of:
an indirect semiconductor; and
a compound semiconductor.

6. The photovoltaic cell of claim 1 wherein the bottom electrode further comprises one of:
stainless steel;
aluminum;
copper;
tin-doped indium oxide; and
any suitable conducting material.

7. The photovoltaic cell of claim 1 wherein the top electrode further comprises one of:
tin-doped indium oxide;
stainless steel;
aluminum;
copper; and
any suitable conducting material.

8. The photovoltaic cell of claim 1 wherein the top electrode configured with the grating further comprises an array of substantially regularly spaced bars.

9. The photovoltaic cell of claim 8 wherein the bars further comprise rectangular cross sections, square cross sections, triangular cross sections, trapezoidal cross sections, semicircular cross sections, and different widths, and aspect ratios.

10. The photovoltaic cell of claim 1 wherein the top electrode configured with the grating further comprises a slab with an array of holes formed in the slab.

11. The photovoltaic cell of claim 10 wherein the array of holes further comprises one of:
a square unit cell pattern;
a hexagonal unit cell pattern;
a triangular unit cell pattern; and
any other suitable unit cell arrangement.

12. The photovoltaic cell of claim 10 wherein the holes further comprise hole shapes having one of:
square;
circular;
rectangular;
elliptical; and
any other suitable shape.

13. The photovoltaic cell of claim 1 wherein the light-absorption layer further comprises a thickness ranging from about 10 nm to about 100 nm.

14. The photovoltaic cell of claim 1 wherein the top electrode further comprises holes having dimensions ranging from about 50 nm to about 500 nm and a lattice spacing ranging from about 100 nm to about 1000 nm.

15. A photovoltaic cell comprising:
a bottom electrode;
a light-absorption layer disposed on the bottom electrode;
a top electrode disposed on the light-absorption layer; and
a grating disposed on the top electrode, wherein the grating is configured so that light incident on the grating is scattered into the light-absorption layer and the grating traps incident light with particular polarizations and incident angles to interact with the light-absorption layer.

16. The photovoltaic cell of claim 15 wherein the light-absorption layer further comprises:
an n-type-semiconductor layer;
a p-type semiconductor layer; and
a middle layer sandwiched between the n-type semiconductor layer and the p-type semiconductor layer.

17. The photovoltaic cell of claim 16 wherein the middle layer further comprises intrinsic nanowires extending from the n-type semiconductor layer to the p-type semiconductor layer.

18. The photovoltaic cell of claim 15 wherein the top electrode further comprises a transparent or a partially transparent conductive layer.

19. The photovoltaic cell of claim 15 wherein the grating further comprises a dielectric material.

20. The photovoltaic cell of claim 15 wherein the bottom electrode further comprises one of:
stainless steel;
aluminum;
copper;
tin-doped indium oxide; and
any suitable conducting material.
